(19) United States
(12) Patent Application Publication
(10) Pub. No.: US 2025/0079132 A1
(43) Pub. Date: Mar. 6, 2025

(54) PLASMA RADICAL EDGE RING BARRIER SEAL

(71) Applicant: Lam Research Corporation, Fremont, CA (US)

(72) Inventor: Adam Christopher Mace, Fremont, CA (US)

(21) Appl. No.: 18/727,065

(22) PCT Filed: Jan. 11, 2022
(86) PCT No.: PCT/US2022/012053

§ 371 Date: Jul. 5, 2024

(51) Int. Cl. H01J 37/32

(52) U.S. Cl. CPC H01J 37/32513

(57) ABSTRACT

A barrier seal ring for use in a plasma chamber includes an outer seal leg extending vertically down from a top surface to a bottom surface along an outer diameter and an inner seal leg extending down from the top surface to an inner diameter. An upper leg portion of the inner seal leg extends at an angle relative to the outer seal leg and a lower leg portion extends down from a bottom of the upper leg portion and an interface is defined between the upper leg portion and the lower leg portion. The interface allows the inner seal leg to fold inward toward the inside surface of the outer seal leg during installation within a groove of a base ring disposed in a lower electrode of the plasma chamber.

### TECHNICAL FIELD

The present disclosure relates to providing a seal ring in a semiconductor process module.

### BACKGROUND

In semiconductor processing, a wafer undergoes various operations to form features that define integrated circuits. For example, in a plasma etching operation, the wafer is received into a plasma chamber and exposed to plasma generated within a plasma processing region defined in the plasma chamber. The plasma interacts with material on the surface of the wafer to remove or modify the materials for eventual removal from the surface. Depending on type of feature to be formed, specific types of reactant gases are supplied to the chamber and radio frequency (RF) signals from a RF power source are applied to energize the specific reactant gases to generate the plasma. The RF signals are provided through the plasma processing region that contains the reactant gases.

The plasma is controlled in the plasma processing region such that the radicals of the plasma are confined to the area above the wafer to cause optimal plasma etching operation. An edge ring is defined to surround a wafer support (e.g., electrostatic chuck) defined in the lower electrode. The constant exposure to the highly reactive plasma radicals causes the edge ring to erode, limiting the edge ring lifetime. As the surface of the edge ring erodes, other components below the edge ring, such as thermal gasket on which the edge ring is supported on the lower electrode, are exposed to the highly reactive radicals of the plasma damaging these components as well. The edge ring needs to be replaced as the edge ring reaches its end of life. Along with the edge ring, the thermal gasket also needs to be replaced.

The transmission path of the RF signals affects how the plasma is generated and how the plasma sheath is managed. For instance, the reactant gases may be energized to a greater extent in specific portions of the plasma processing region where larger amounts of RF signal power is transmitted, leading to spatial non-uniformities in the plasma characteristics across the plasma processing region. Some of the plasma characteristics causing spatial non-uniformities include non-uniformity in ion density, ion energy, reactant gas density, etc. The spatial non-uniformities in the plasma characteristics can translate to non-uniform results in plasma processing results on the wafer.

To address spatial non-uniformity and to control profile of plasma sheath, a tunable edge sheath (TES) assembly is defined to independently power an edge electrode. The edge electrode is separate from the main electrode that is used to send RF signals to power the reactant gases received in the plasma processing region. The TES assembly includes a plurality of quartz components/elements, ceramic support and the edge electrode connected to a RF power source to provide the RF power to the plasma processing region via the edge ring. With the introduction of the TES assembly, additional components (e.g., plastic components) were also introduced that were susceptible to attack by the plasma radicals. The erosion of these TES assembly components due to radical attack has become a limiting factor influencing mean time between clean and high cost of consumables adder.

It is in this context that embodiments of the invention arise.

### SUMMARY

In the various implementations discussed herein, a barrier seal ring is introduced into a tunable edge sheath (TES) assembly defined in a lower portion of a plasma process chamber (or simply referred to as “plasma chamber”). The lower portion of the plasma chamber includes a lower electrode, in some implementation, that is powered by a radio frequency (RF) power source, and the TES assembly is defined below an edge ring that surrounds a wafer support surface (e.g., electrostatic chuck (ESC)) defined in the lower electrode. The TES assembly is introduced into the plasma chamber to better control profile of the plasma sheath over the edge of the wafer. The TES assembly is provided to independently power an edge electrode disposed below the edge ring, which is different from a main electrode that powers the ESC (i.e., lower electrode) in the plasma chamber. The barrier seal ring is integrated into the TES assembly and is used to seal a gap between some of the components of the TES assembly so that the plasma radicals are successfully blocked from reaching other underlying components (e.g., plastic components) of the TES assembly. The barrier seal ring is made of a material that has a lower erosion rate. Blocking the path to the components of the TES assembly results in improved lifetime of the additional components and reduced cost of consumables and improved mean time between clean of the components of the TES assembly.

Typically, the edge ring is designed so as to include gaps between the edge ring and the different components adjacent to the edge ring. These gaps are introduced in consideration of thermal expansion allowances and/or mechanical tolerance allowances. The downside of having the gaps between the edge ring and the different components adjacent to the edge ring is that the gaps provide a path of least resistance for the plasma radicals to follow and attack a material disposed below the edge ring in the plasma chamber. Before introduction of the TES assembly in the plasma chamber, the gaps between the different components of an edge ring assembly did not affect the integrity of the different components of the plasma chamber below the edge ring, as the different components of the lower electrode were less susceptible to the attack from the plasma radicals. However, with the introduction of the TES assembly, insulating components, such as plastic components, were introduced to enclose a conductive rod that provided power to the edge electrode. The gaps between the edge ring and the adjacent components resulted in the plasma radicals to flow through the gaps and attack the susceptible plastic components, resulting in mechanical weakening of the components and visible erosion of the part contained within (e.g., conductive rod).

To prevent the attack on the susceptible insulating components (e.g., plastic components), the barrier seal ring was introduced above the plastic components of the TES assembly so as to block the flow of the plasma radicals toward the plastic components. The barrier seal ring is integrated into a groove defined in a base ring of the TES assembly that is disposed below the edge ring. The base ring is made of quartz. The barrier seal ring is made of a material that is less susceptible to plasma radicals and is flexible so that it can be easily pushed into place within a groove defined in the base ring. The base ring is disposed adjacent to and surround the TES ring and a portion of a ceramic support element disposed below the TES ring. Insulating material (e.g., plastic or ceramic component) of the TES assembly is embedded in the ceramic support element defined below the TES ring and surrounds the ESC. The barrier seal ring is used to seal the gap between a TES ring and the base ring. By successfully sealing the gap, the barrier seal ring prevents the plasma radicals from reaching the insulating material embedded in the ceramic support element of the TES assembly, thereby preserving the integrity of the insulating material and the conductive rod encapsulated within. By preventing erosion of the insulating material, the barrier seal ring improves the mean time between clean and reduces cost of consumables as the insulating material, such as the plastic components, can be reused for multiple wet cleans.

In one implementation, a barrier seal ring for use in a plasma chamber is disclosed. The barrier seal ring includes an outer seal leg extending vertically down along an outer diameter. The outer seal leg includes an upper chamfer and a lower chamfer defined along the outer diameter of the barrier seal ring. An inner seal leg is connected to a top portion of the outer seal leg. The inner seal leg is oriented at an angle relative to the outer seal leg. The inner seal leg comprises an upper leg portion and a lower leg portion. The lower leg portion of the inner seal leg forms an initial gap of a first distance with the outer seal leg. The lower leg portion is configured to flex towards the outer seal leg to create a second gap that is less than the first distance of the initial gap but is greater than zero. The barrier seal ring is configured to sit in a groove of a first ring and provide a seal when the inner seal leg is pressed against a second ring. The first and the second rings are part of the plasma chamber.

### DESCRIPTION OF DRAWINGS

FIG. 1 illustrates a simplified block diagram of a lower portion of a plasma chamber in which a barrier seal ring is employed within a tunable edge sheath assembly, in accordance with one implementation.

FIG. 2 illustrates a side perspective view of a base ring with a groove for receiving the barrier seal ring thereof.

FIG. 3 illustrates an expanded cross-sectional view of the barrier seal ring thereof.

FIG. 4 illustrates an expanded cross-sectional view of the barrier seal ring of FIG. 3 identifying some dimensions thereof.

FIG. 5 illustrates an expanded cross-sectional view of the barrier seal ring of FIG. 3 identifying positional profiles thereof.

FIG. 6 is a top perspective view thereof.

FIG. 7 is a side view thereof.

FIG. 8 is a top view thereof.

FIG. 9 is a bottom view thereof.

FIG. 10A is a side view of FIG. 7 used for providing magnified cross-sectional view of a barrier seal ring thereof.

FIG. 10B is a magnified cross-sectional view of a barrier seal ring thereof.

### DETAILED DESCRIPTION

Features of various components of a barrier seal ring used within a plasma process module (alternatively referred to herein as “process module”) to block flow of plasma radicals toward different underlying components of a plasma chamber defined in the process module and to prevent attack on different components, are described in detail. The barrier seal ring is integrated into a first ring that is adjacent to and surrounds a second ring defined in a lower portion of the process module. In one implementation, the first ring is a base ring disposed below a first portion of an edge ring that surrounds a substrate support surface defined in the lower portion of the process module and the second ring is a tunable edge sheath (TES) ring of a TES assembly defined below a second portion of the edge ring. The barrier seal ring is used to effectively block a path between the first ring and the second ring used by the plasma radicals to attack the different underlying components, including insulating (e.g., plastic) components of the TES assembly. A groove is defined along an inside sidewall of the base ring. The groove is sized for receiving the barrier seal ring. The barrier seal ring is made of a material that is flexible and is less susceptible to erosion from fluorine and/or other components of the plasma radicals. Chamfers are provided at various outside corners (both top and bottom) of the barrier seal ring to allow the barrier seal ring to be pushed into place within the groove to ensure proper seating and full mating with inside sidewall of the groove defined in the base ring. The size and flexible nature of the barrier seal ring ensures that the barrier seal ring is fully received and held in place within the groove without causing any interference with lower outer corner of the groove and between the components of the barrier seal ring. Additionally, the size, shape and design of the barrier seal ring are defined to seal the path between the base ring and the adjacent components in the lower portion of the process module so that plasma radicals cannot find their way to attack underlying components.

Broadly speaking, a plasma chamber includes an upper member (also referred to interchangeably as “upper portion”), a lower member (also referred to interchangeably as “lower portion”) and sidewalls that extend between the upper and the lower members to define a plasma processing region within. The upper member is configured to be coupled to gas sources to supply reactant gases to the plasma processing region. The lower member includes at least an electrostatic chuck (ESC) that is coupled to a radio frequency (RF) power source, which provides power to the reactant gases through the ESC to generate plasma in the plasma processing region. The RF power source providing power to the reactant gases through the ESC represents the main power source and the ESC acts as the main electrode. In addition to the main power source, the lower member also includes a second RF power source that is used to provide RF power to control plasma sheath profile above an edge ring disposed to surround the ESC. The second power source is coupled to an edge electrode embedded within a tunable edge sheath (TES) ring of a TES assembly included in the lower member. The TES assembly is used to control characteristics of the plasma sheath near the peripheral edge of the wafer received on the ESC and over the edge ring, wherein the characteristics that can be controlled include plasma density, attracting or repelling ions, etc. By controlling the characteristics of the plasma, the TES assembly enables tuning of the plasma sheath (i.e., influencing plasma sheath profile) at the wafer edge to improve radial uniformity across the surface of the wafer. Improving radial uniformity results in increased yield and improved quality of devices formed on the wafer.

The introduction of the TES assembly in the lower member, however, also introduces plasma susceptible elements, such as plastic components, that are used to enclose certain components (e.g., a conductive rod coupled to the second RF power supply) of the TES assembly.

For instance, the plastic component with the conductive rod is embedded in a ceramic support element disposed below the TES ring. The plastic component acts as an insulator surrounding the conductive rod. The conductive rod is coupled to the RF power source at a first end and extends through the plastic component and couples to the edge electrode embedded in the TES ring at a second end. The TES ring is defined below a portion of an edge ring surrounding the ESC. As different wafers undergo processing using plasma generated in the plasma processing region, the edge ring adjacent to the ESC on which the wafer is received is constantly exposed to the plasma radicals. The constant exposure erodes the surface of the edge ring. As the surface of the edge ring erodes, a gap provided between the edge ring and the adjacent components, such as cover ring, TES ring (i.e., coupling ring), etc., begins to widen and the plasma radicals begin to find a path through the gap to the underlying components of the TES assembly. The gap between the edge ring and the adjacent components is provided in consideration of thermal expansion tolerances or mechanical tolerances. To prevent the radical erosion of the underlying components, particularly the susceptible plastic components of the TES assembly, and to improve the mean time between clean (MTBC) and to reduce cost of consumables (CoC), the barrier seal ring is introduced in the path above the plastic components so as to block the flow of the plasma radicals toward the plastic components of the TES assembly and to prevent the plasma radicals from attacking the plastic components. The barrier seal ring is received into a groove defined in the inner sidewall of a base ring (e.g., first ring) that is adjacent to and surrounds the TES ring (e.g., second ring).

The various parts (i.e., components) that are used to surround the ESC are selected to close any high voltage pathway between the ESC and the ground ring. In order to avoid arcing risks and to close the high voltage pathway, the various parts were disposed to physically touch one another. For example, the edge ring was coupled to the ESC using a thermal gasket. Alternately, the edge ring was directly coupled using a O-ring. A base ring was disposed below a portion of the edge ring. The other portion of the edge ring and the base ring both rested on a ceramic support (i.e., an insulator ring) that surrounded the ESC. This stacking of the components leaves a gap particularly between a bottom surface of the edge ring and the base ring. The challenge with the edge ring design is that there is no way of closing the gap without a flexible component. The thermal gasket and other means of coupling the edge ring were susceptible to the plasma radicals as much as the edge ring was, and therefore did not provide the required flexibility and chemical/mechanical strength.

The barrier seal ring is designed to provide the required flexibility and the chemical/mechanical strength to ensure that the path is completely sealed in order to preserve the integrity of the plastic component and other underlying components. The barrier seal ring includes an outer seal leg extending for an outer diameter that is equal to an outer diameter of a groove defined in a base ring into which the barrier seal ring is received, and an inner seal leg extending to an inner diameter, which is equal to an inner diameter of the groove. The width of the barrier seal ring is defined to ensure that there is always contact between the outside diameter of the barrier seal ring and the inside diameter of the base ring groove, as well as contact between the inside diameter of the barrier seal ring and the outside diameter of the adjacent TES ring. The outer diameter of the barrier seal ring is defined to ensure the outer diameter of the barrier seal ring compresses within the base ring during install to ensure the seal is center and maintains contact with the base ring groove inside diameter. The inside diameter of the barrier seal ring is defined to ensure an interference fit with the outer diameter of the TES ring and is designed to flex to ensure contact is always maintained. The material used to define the barrier seal ring is selected to be less susceptible to the plasma radical so that the barrier seal ring can be reused. A height of the outer seal leg at the outer diameter is defined to ensure the barrier seal ring does not overfill the height of the groove in the base ring in which the barrier seal ring sits, at operative temperatures of the plasma chamber. Heights of the outer seal leg and the inner seal leg of the barrier seal ring and the size of the groove are designed to ensure that the inner seal leg can fold into the groove when flexed inward. Chamfers are defined in the outer corners of the barrier seal ring to ensure that the barrier seal ring can be received into the groove of the base ring without interference with any surfaces of the base ring defining the groove and between the inner and the inner seal legs. It should be noted that use of the barrier seal ring in a TES assembly to protect the underlying components from plasma attack is one use of the barrier seal ring. The concept of the barrier seal ring can be extended for use in the plasma chamber in places other than the TES assembly to prevent flow of the plasma or other gases or other gaseous by-products into regions that should not receive such flow and for use in successfully sealing other areas.

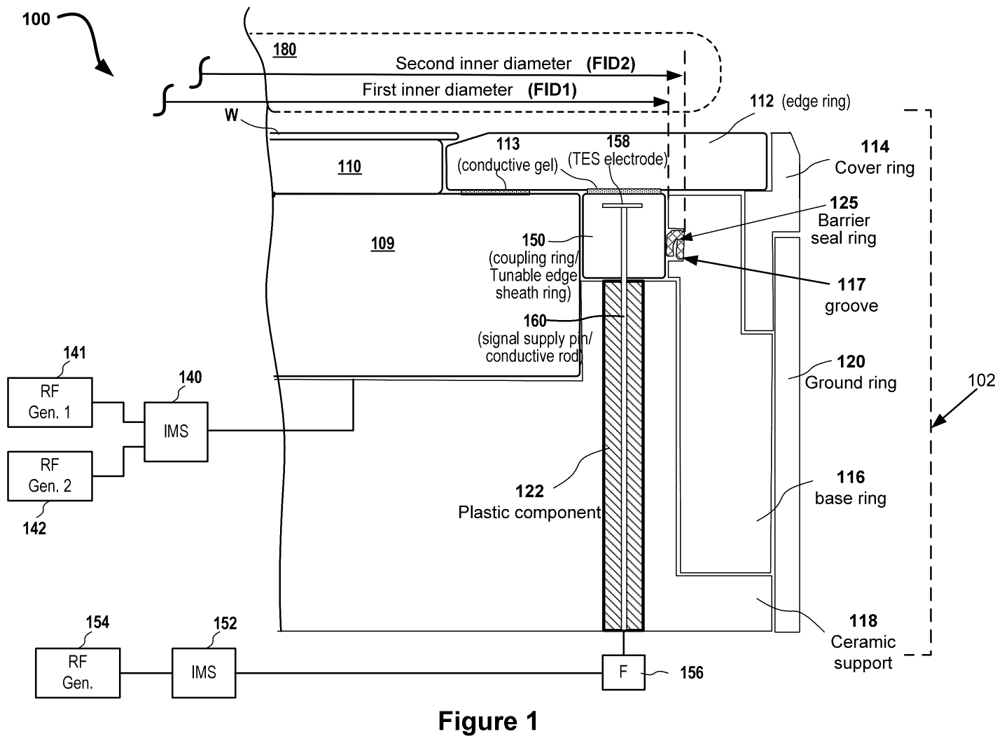

FIG. 1 shows a vertical cross-sectional view of a lower portion (i.e., lower member 102) of a plasma process chamber (or simply referred to henceforth as “plasma chamber”) of a process module 100 used in wafer processing, in accordance with an implementation. The plasma chamber of the process module 100 is designed to include a barrier seal ring 125 within a TES assembly defined in the plasma chamber in order to prevent the plasma radicals from reaching the underlying components of the TES assembly. The plasma chamber in the process module 100 includes an electrode 109, which in some implementations, is formed of conductive element, such as aluminum. A ceramic layer 110 is formed on a top surface of the electrode 109. The ceramic layer 110 is configured to receive and support a wafer W when plasma processing operations are to be performed on the wafer W. In some implementations the ceramic layer 110, the electrode 109, and associated components define an electrostatic chuck (ESC).

Power is provided to the ESC from a radio frequency (RF) power source. In one implementation, the RF power source includes one or more RF signal generators providing power(s) through a matching circuit, such as an impedance matching system (IMS) 140. In the example implementation shown in FIG. 1, the RF power source includes two RF signal generators to provide the power to the ESC. Accordingly, a first RF signal generator 141 is employed to provide RF power of about 60 MHz and a second RF signal generator 142 is employed to provide RF power of about 400 kHz, via the impedance matching system (IMS) 140, to the electrode 109. The RF power source including the first RF signal generator 141, the second RF signal generator 142 and the IMS 140 represent the main power source of the process module and the electrode 109 is defined to be the main electrode. The RF power provided to the electrode 109 is applied to reactive gases (i.e., gaseous species) introduced in the plasma processing region 180 defined above the ceramic layer 110, to produce plasma for wafer processing operation, such as etching. An edge ring 112 is defined to surround the ceramic layer 110, and is configured to facilitate extension of a plasma sheath radially outward beyond the peripheral edge of the wafer W so as to improve process results near the peripheral edge of the wafer W. In addition to the edge ring, the ESC and the RF power source, the lower member of the plasma chamber also includes a cover ring 114 defined adjacent to and surround the edge ring 112. The cover ring 114 is made of insulating material. Gaps are introduced adjacent to the edge ring 112 in consideration of thermal expansion allowances or mechanical tolerance allowances.

A Tunable Edge Sheath (TES) assembly is implemented in the lower member of the plasma chamber to better control plasma sheath characteristics of the plasma generated in the plasma processing region 180. The TES assembly is disposed below the edge ring 112 to better control the plasma sheath profile, particularly at the peripheral edge region of the wafer W, by controlling the plasma sheath characteristics. The TES assembly includes a TES electrode (also referred to as “edge electrode”) 158 disposed (embedded) within a TES ring (also referred to herein as coupling ring) 150. The TES ring 150 is disposed below a first portion of the edge ring 112 and is configured to surround at least a first portion of the electrode 109. In one implementation, an electrically conductive gel 113 or thermal gasket (not shown) is used to install the edge ring 112 over a portion of the top of the electrode 109 and over the TES (coupling) ring 150. In alternate implementation, the edge ring 112 is directly attached to the TES ring 150. In other implementations, other installation means may be engaged to install the edge ring 112 over portions of the electrode 109 and the TES ring 150. A ceramic support 118 is disposed below the TES ring 150 and is configured to surround a second portion of the electrode 109. An insulating component is embedded within the ceramic support 118 and extends a first length defined from a top surface to the bottom surface of the ceramic support 118. In one implementation, the insulating component is a sleeve 122. In some implementations, the sleeve 122 is made of a plastic or ceramic or other insulating material, to protect and encapsulate a conductive rod 160. A TES radiofrequency (RF) signal generator 154 is engaged to provide RF power through a TES impedance matching system (IMS) 152 to the TES electrode 158. Consequently, a first end of the conductive rod 160 is coupled to the TES RF signal generator 154 through the TES IMS 152 and a second end of the conductive rod 160 is coupled to the TES electrode 158. In one implementation, the power from the TES RF signal generator 154 is provided to the TES electrode 158 through a TES RF signal filter 156. The RF power generated by the TES RF signal generator 154 is transmitted through the TES IMS 152 and the TES RF signal filter 156 (where available) to the conductive rod 160. The conductive rod 160 extends a second length, wherein the second length is defined to include the first length of the sleeve 122 within the ceramic support 118 and a length within the TES ring 150 from a bottom surface of the TES ring 150 to the bottom of the TES electrode 158. The TES assembly is used to control characteristics of the plasma near the peripheral edge of the wafer W, such as controlling properties of the plasma sheath, plasma density, and attracting or repelling ions. Through the application of RF power to the TES electrode 158, the TES system enables tuning profile of the plasma sheath at the edge of the wafer to improve radial uniformity.

A base ring 116 is defined below a second portion of the edge ring 112. The base ring 116 is disposed adjacent to and surrounds the TES ring 150 and a portion of the ceramic support 118 to electrically insulate the components of the TES assembly. In one implementation, the base ring 116 is made of quartz. A groove 117 is defined in a portion of an inside sidewall of the base ring 116 that is adjacent to the TES ring 150. The location of the groove 117 in the inside sidewall of the base ring 116 is identified to be over the top surface of the ceramic support 118. The groove 117 is defined to extend from a first inner diameter (‘FID1’) to a second inner diameter (‘FID2’) of the base ring 116, wherein the FID2 is greater than the FID1. The groove 117 is defined to have dimensions that are appropriate to receive a barrier seal ring 125. The barrier seal ring 125 is received into the groove 117 to block the path defined by a gap between the TES ring 150 and the base ring 116. A ground ring 120 is defined adjacent to and surround at least a portion of the cover ring 114, the base ring 116, and a portion of the ceramic support 118. As the barrier seal ring 125 is used to block the path of the plasma radicals from finding their way through the gaps defined between edge ring and other components of the lower electrode, the barrier seal ring 125 is also referred to as a “plasma radical edge ring barrier seal”.

Due to constant exposure to the reactive radicals of the plasma, the surface of the edge ring 112 starts eroding. The gaps defined between the edge ring 112 and the adjacent components (e.g., cover ring 114), in consideration of the thermal expansion allowances or mechanical tolerance allowances provide pathways for the plasma radicals to travel and erode weak materials along the way. In some implementations, the TES assembly incorporates plastic shaft(s) into the design for encapsulating the conductive rod(s). Referring to FIG. 1, without the barrier seal ring 125, the plasma radicals can travel along the gaps (e.g., gaps between edge ring 112 and cover ring 114, between the edge ring 112 and base ring 116, between the coupling ring 150 and base ring 116, etc.,) to reach the sleeve 122. Plasma radicals can cause mechanical/material weakening of the sleeve 122 and such erosion can shorten the useful lifespan of the sleeve 122 as well as damage the conductive rod 160 encapsulated within. As the surface erosion of the edge ring 112 progresses with each process operation, the gaps between the edge ring 112 and the adjacent components widen enabling the radicals to move more freely toward the target of attack (e.g., the sleeve 122 and conductive rod 160).

In some implementations, the barrier seal ring 125 is installed in the portion of the base ring 116 that is above the sleeve 122 and is used to effectively seal the gap between the base ring 116 and the TES ring 150. Placement of the barrier seal ring 125 adjacent to the outer sidewall of the TES ring 150 prevents plasma radicals from reaching the underlying components, such as sleeve 122, of the TES assembly. Preventing the plasma radicals from moving beyond the area where the barrier seal ring 125 ensures that the sleeve 122 is not exposed to plasma radicals and the integrity of the sleeve 122 (which may be made of plastic) and the conductive rod embedded within is preserved. Such configuration would improve mean time between clean (MTBC) and reduce the cost of replacement of sleeve 122 (i.e., reduces cost of consumables (CoC)). Therefore, the preserved sleeve 122 can be reused multiple times after each clean cycle.

In addition to the lower member 102, the plasma chamber of the process module 100 includes an upper member (not shown) for supplying reactive gases to the plasma processing region 180, and sidewalls extending between the upper member and the lower member 102 encapsulating the plasma processing region 180. In some implementations, the lower member 102 also includes an exhaust port through which exhaust gases from plasma processing operations are removed. In some implementations, the exhaust port may be connected to a vacuum device to provide a suction force to remove the exhaust gases. In some implementations, the plasma chamber within the process module 100 is formed of aluminum. However, in other implementations, the plasma chamber can be formed of essentially any material that provides sufficient mechanical strength, have thermal performance capability and chemical compatibility with the gaseous and other materials exposed during plasma processing operations conducted within the plasma chamber. At least one sidewall of the plasma chamber includes an opening operated by a door through which a semiconductor wafer W is introduced into and removed from the plasma chamber. In some implementations, the door is configured as a slit-valve door.

In some implementations, the semiconductor wafer W is a substrate undergoing a fabrication procedure. For ease of understanding and discussion, the semiconductor wafer W is referred to simply as wafer W hereafter. However, it should be understood that in various implementations, the wafer W can be essentially any type of substrate that is subjected to a plasma-based fabrication process. For example, in some implementations, the wafer W can be a substrate formed of silicon, SiC, or other substrate materials, and can include glass panels/substrates, metal foils, metal sheets, polymer materials, or the like. Further, in various implementations, the wafer W may vary in form, shape, and/or size. For example, in some implementations, the wafer W may correspond to a circular-shaped semiconductor wafer on which integrated circuit devices are defined. In alternate implementations, the wafer W may correspond to non-circular substrate (e.g., rectangular, oval, etc.), or the like. Similarly, in the implementations where the circular-shaped wafer W is being processed, the wafer W can have varying diameters, such as 200 mm (millimeters), 300 mm, 450 mm, or any other size.

In the plasma chamber of the process module 100, the electrode 109 is formed of aluminum, in one implementation. In alternate implementations, the electrode 109 can be formed of other electrically conductive material that has comparable mechanical strength, and compatible thermal and chemical performance characteristics. The ceramic layer 110 is configured to receive and support the wafer W during performance of plasma processing operations on the wafer W. In some implementations, the ceramic layer 110 includes a radial arrangement of two or more clamp electrodes (not shown) for generating an electrostatic force to hold the wafer W to the top surface of the ceramic layer 110 during plasma processing operations. In one implementation, the ceramic layer 110 includes two clamp electrodes (not shown) that are disposed diametrically opposite to one another and configured to operate in a bipolar manner to provide a clamping force to the wafer W during process operations. The clamp electrodes are connected to a direct current (DC) supply configured to generate a controlled clamping voltage to hold the wafer W against the top surface of the ceramic layer 110. The DC supply is electrically connected to the clamp electrodes via the ceramic layer 110 and the electrode 109. The DC supply is connected to a control system (not shown) through one or more signal conductors so as to allow the control system to control the clamping force provided to the waver W.

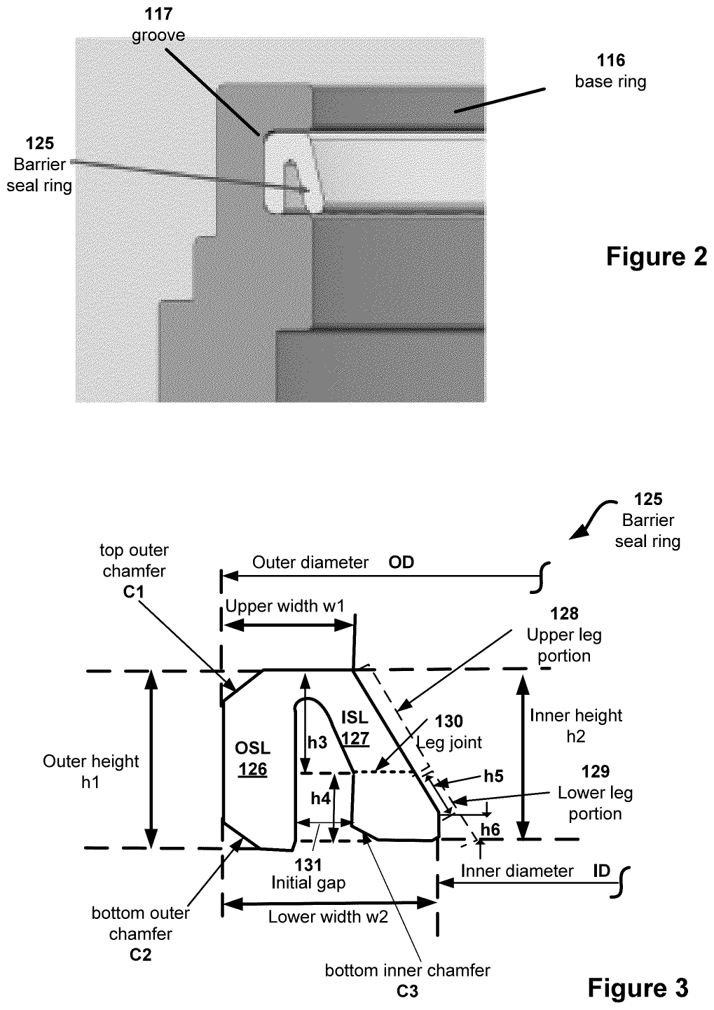

FIG. 2 illustrates an expanded perspective view of the base ring 116 into which the barrier seal ring 125 is incorporated, in one implementation. A groove 117 is defined on an inside sidewall of the base ring 116. The location of the groove 117 is defined in an area of the base ring 116 that is above a top surface of the ceramic support 118 defined in the lower member 102 of the plasma chamber within the process module 100 (see e.g., FIG. 1). The groove 117 is defined to have an inside sidewall with a top inner radii defined at the top of the inside sidewall and a bottom inner radii defined at the bottom of the inside sidewall. The dimensions and geometry of the barrier seal ring 125 are designed to fit within the dimensions and geometry of the groove 117 to ensure the barrier seal ring 125 can be installed easily and snugly into the groove 117. The material for the barrier seal ring 125 is chosen to withstand exposure to the plasma radicals and is flexible to be pushed in place within the groove 117 with application of appropriate force. The design and flexible nature of the barrier seal ring 125 ensures that the gap between the TES ring 150 and the base ring 116 is completely covered, thereby preventing the plasma radicals from finding a path to attack the sleeve 122.

FIG. 3 illustrates an expanded vertical, cross-sectional view of the barrier seal ring 125 used to seal a gap between a TES ring 150 and a base ring 116 of a TES assembly, in one implementation. The barrier seal ring 125 is defined by an outer seal leg 126 and an inner seal leg 127. The outer seal leg 126 is defined to extend vertically down for an outer height of ‘h1’ along an outer diameter ‘OD’. In one implementation, the outer height h1 is defined to be between about 4.7 mm and about 5.0 mm. In another implementation, the outer height h1 is defined to be about 4.85 mm. In one implementation, the outer seal leg 126 is uniform in thickness along the length of the outer seal leg 126. In one implementation, the thickness of the outer seal leg 126 is defined to be between about 1.32 mm and about 1.72 mm. In an alternate implementation, the thickness of the outer seal leg 126 can vary along the length of the outer seal leg 126. A top outer corner and a bottom outer corner (i.e., the corners along the outer diameter) of the outer seal leg 126 are designed to include chamfers (C1, C2). The profiles of the chamfers (C1, C2) at the top and the bottom outer corners on the outer seal leg 126 are designed to match geometry at the inner radii of a corresponding top corner and a bottom corner of an inside sidewall of the groove 117 into which the barrier seal ring 125 is to be received. The profile of the chamfers includes at least an angle and a length between the adjacent surfaces. In one implementation, a length of the top outer chamfer C1 is defined to be equal to a length of the bottom outer chamfer C2. In this implementation, the length of the chamfers C1, C2 is defined to be between about 0.60 mm and about 1.0 mm. In an alternate implementation, the length of the chamfers C1 and C2 is defined to be about 0.8 mm. In another implementation, the length of the top outer chamfer C1 is different from the length of the bottom outer chamfer C2 and the difference in the length is driven by the geometry of the groove 117 and the inner radii of the top corner and bottom corner of the inside sidewall of the groove 117. In one implementation, an angle of the top outer chamfer C1 and the bottom outer chamfer C2, is defined to be equal. In some implementations, the angle of chamfers C1 and C2 are defined in relation to the outer diameter side of the barrier seal ring (e.g., angle of inclination of the chamfers C1 and C2 with respect to the outer sidewall of the barrier seal ring). In alternate implementations, the angle of chamfers C1 and C2 are defined in relation to the upper surface of the barrier seal ring 125. In some implementations, the angle of the chamfers C1, C2 is defined to be about 45°. In alternate implementations, the angle of the chamfers C1, C2, is equal but is greater than or less than 45° and depends on the profile of the top and bottom corners of the inside sidewall of the groove 117. In one implementation, top corner and the bottom corner of the inside sidewall of the groove 117 is defined to be at right angle. In alternate implementations, the angle of the top corner is different from the angle of the bottom corner of the groove 117, and each of the angles of the top and the bottom corners being less than 90°. In this implementation, the angle of the top outer chamfer C1 and the angle of the bottom outer chamfer C2 are defined to closely match the angular profile of the top and bottom corners of the inside sidewall of the groove 117 with the angle of the top outer chamfer C1 being different from the angle of the bottom outer chamfer C2.

The inner seal leg 127 is defined to extend from a top portion of an inside surface of the outer seal leg 126 for an inner height of ‘h2’. In some implementations, the profile of the inner seal leg 127 is defined to be different from the profile of the outer seal leg 126. In one implementation, the profile of the inner seal leg 127 is angled with respect to the top surface while the profile of the outer seal leg 126 is straight (i.e., perpendicular with respect to the top surface). In one implementation, the inner height h2 of the inner seal leg 127 is defined to be different from the outer height h1 of the outer seal leg 126. In one implementation, the height h2 is less than height h1. In one implementation, the inner height h2 of the inner seal leg 127 is defined to be between about 4.45 mm and about 4.75 mm. In another implementation, the inner height h2 of the inner seal leg 127 is defined to be about 4.6 mm. The inner seal leg 127 is defined by an upper leg portion 128, a lower leg portion 129 and an interface connecting the upper leg portion 128 and the lower leg portion 129. The upper leg portion 128 is connected to a top portion of the inside surface of the outer seal leg 126 and is oriented at an angle relative to the outer seal leg 126 so as to define an initial gap 131 between the inside surface of the outer seal leg 126 and the inside surface of the lower leg portion 129 of the inner seal leg 127. In one implementation, the angle at which the upper leg portion 128 extends relative to the inside surface of the outer seal leg 126 is defined to be an acute angle. In one implementation, the lower leg portion 129 extends down from a bottom surface of the upper leg portion 128, such that an inside surface of the lower leg portion 129 extends vertically down and is substantially parallel (+/−5%) to the inside surface of the outer seal leg 126. An outside surface of the lower leg portion includes a top lower leg portion and a bottom lower leg portion. The top lower leg portion extends a first leg height ‘h5’ and the bottom leg portion extends for a second leg height ‘h6’. In one implementation as illustrated in FIG. 3, the outside surface of the top lower leg portion follows a contour of an outside surface of the upper leg portion 128 and the outside surface of the bottom lower leg portion extends vertically down from a bottom of the top lower leg portion so as to be substantially parallel (+/−5%) to the inside surface of the outer seal leg 126. It should be noted that the profile of the outer seal leg and the inner seal leg defined herein are provided as examples and that other profiles can also be envisioned.

In one implementation, the thickness of the inner seal leg 127 is uniform throughout the inner height h2. In alternate implementations, the thickness of the upper leg portion 128 of the inner seal leg 127 is different from that of the lower leg portion 129. In one implementation, the upper leg portion 128 is uniform in thickness (as illustrated in FIG. 3) and the lower leg portion 129 is uniform in thickness (not shown). However, the thickness of the upper leg portion 128, in some implementations, is greater than or less than the thickness of the lower leg portion 129. In alternate implementation, the thickness of the upper leg portion 128 gradually increases from the top surface to the bottom surface of the upper leg portion 128. Similarly, the thickness of the lower leg portion 129 gradually increases from the top surface to the bottom surface of the lower leg portion 129, wherein the thickness at the top surface of the lower leg portion 129 being equal to the thickness at the bottom surface of the upper leg portion 128. As can be seen, the barrier seal ring 125 can have different profiles with each profile being defined by the geometry and dimensions of the inner seal leg 127 and the outer seal leg 126, angle at which the upper leg portion 128 is disposed in relation to the inside surface of the outer seal leg 126, amount of initial gap desired between the outer seal leg 126 and the inner seal leg 127, profile of the outer surface of the inner seal leg, to name a few.

The initial gap 131 can be adjusted by flexing the inner seal leg inward toward the outer seal leg by applying a force at the inner seal leg. The force is applied, in one instance, during installation of the TES ring 150. In one implementation, the initial gap 131 is reduced by the flexing of the inner seal leg inward to define folded gap 132 (shown in FIG. 5). In one implementation, the degree of inward flexing varies for the upper leg portion 128 and the lower leg portion 129. For instance, the upper leg portion 128 flexes inward for a lesser degree than the lower leg portion 129. In this instance, when inner seal leg 127 is bent towards outer seal leg 126, the height h1 does not change—i.e., the top surface of the barrier seal ring 125 is configured to not budge or protrude upward when inner seal leg 127 is moving toward outer seal leg 126. Similarly, when the inner seal leg 127 is relaxed (i.e., moving away) from the outer seal leg 126, the top surface of the barrier seal ring 125 should not cave.

A bottom inner corner of the lower leg portion 129 is defined to include a chamfer C3. In one implementation, the length of the chamfer C3 in the bottom inner corner of the inner seal leg 127 is defined to be between about 0.4 mm and about 0.6 mm. In an alternate implementation, the length of chamfer C3 is defined to be about 0.5 mm. In one implementation, the angle of the chamfer C3 is defined to allow easy flexing of the lower leg portion 129 and, hence, of the inner seal leg 127.

In one implementation, the angular profile of the inner seal leg 127 results in having varying widths along the top and the bottom surfaces of the barrier seal ring 125. In one implementation, the barrier seal ring 125 extends an upper width of ‘w1’ at the top surface and a lower width of ‘w2’ at the bottom surface. In one implementation, the upper width w1 is defined to be between about 2.4 mm and about 2.8 mm. In another implementation, the upper width w1 is defined to be about 2.65 mm. In one implementation, the lower width w2 is defined to be between about 4.2 mm and about 4.6 mm. In another implementation, the lower width w2 is defined to be about 4.4 mm.

In one implementation, the groove 117 defined on an inside sidewall of the base ring 116 extends from a first inner diameter ‘FID1’ to a second inner diameter ‘FID2’, wherein FID1 of the groove 117 is less than FID2. The FID1 of the groove 117 is greater than an inner diameter ‘ID’ of the barrier seal ring 125. Further, in one implementation, the FID2 of the groove 117 is equal to an outer diameter ‘OD’ of the barrier seal ring 125. In an alternate implementation, the FID2 of the groove 117 is less than the OD of the barrier seal ring 125. In this implementation, when the barrier seal ring 125 is installed, the force compresses the OD against the inner sidewall of the groove 117. In one implementation, the outer diameter OD, inner diameter ID of the barrier seal ring 125, and the first inner diameter (FID1) and second inner diameter (FID2) of the groove 117 depend on a size of the ESC. In one implementation, the outer diameter OD of the barrier seal ring 125 is defined to be between about 350 mm and about 355 mm. In another implementation, the outer diameter OD of the barrier seal ring 125 is defined to be about 352 mm. In yet another implementation, the outer diameter of the barrier seal ring 125 is defined to be between about 383 mm and about 387 mm. In some implementations, the outer diameter OD of the barrier seal ring 125 is defined to be about 385.5 mm.

The interface defined between the upper leg portion 128 and the lower leg portion 129 of the inner seal leg 127 is configured to allow the inner seal leg 127 to flex inward toward the inside surface of the outer seal leg 126. During installation, a force ‘F’ is applied along the inner diameter ID of the barrier seal ring 125 (i.e., at an outside surface of the lower leg portion 129) and the design and material used for the barrier seal ring 125 allows the inner seal leg 127 to flex and fold inward into the initial gap 131 and toward the outer seal leg 126. In one implementation, an extent to which the inner seal leg 127 is allowed to fold is limited to a folding angle. The folding angle, in one implementation, is defined to maintain a folded gap 132 between a tip of the outer seal leg 126 and the inside surface of the inner seal leg 127. The folded gap 132 is less than the initial gap 131 and, in one implementation, is defined to ensure that the flexing of the inner seal leg 127 does not cause interferences with any parts/surfaces of the outer seal leg 126 and the surfaces of the groove 117, base ring 116. In an alternate implementation, the inner seal leg 127 can be folded so that the bottom inside corner of the inner seal leg 127 where the chamfer C3 is defined touches the inside wall of the outer seal leg 126 without leaving any folded gap 132. The extent to which the inner seal leg 127 can be folded is defined to ensure that sufficient amount of the inner seal leg extends out toward the TES ring 150 so as to block the gap between the TES ring 150 and the base ring 116. The force is applied to the barrier seal ring 125, during installation, to ensure that the barrier seal ring 125 is seated properly within the groove 117 and the outer surface of the outer seal leg 126 fully mates with the inside sidewall of the groove 117. In one implementation, the term ‘fully mates’ is defined by the length of the outer wall of the outer seal leg 126 fully abutting the length of the inner sidewall of the groove 117. The chamfers C1, C2 further assist in positioning the barrier seal ring 125 in the groove 117 and chamfer C3 assists in the flexing of the inner seal leg 127.

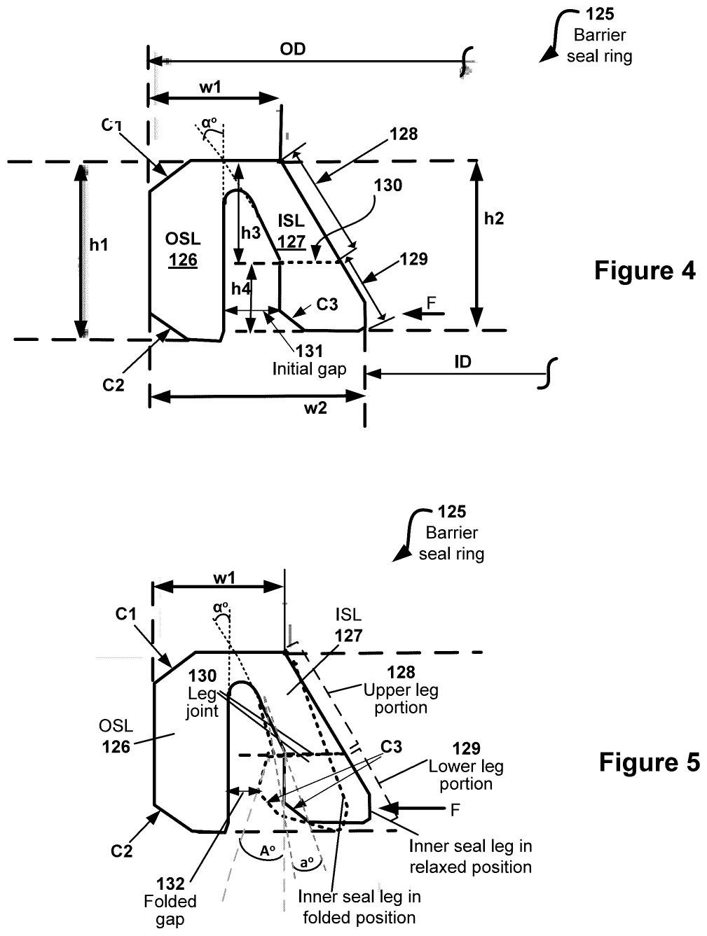

FIG. 4 identifies additional features of the barrier seal ring 125, in one implementation. As shown, the inner seal leg 127 includes an upper leg portion 128 and a lower leg portion 129. The upper leg portion 128 extends down for a height ‘h3’ from the top surface of the barrier seal ring 125, and the lower leg portion 129 extends down from the bottom surface of the upper leg portion 128 for a height ‘h4’. In this implementation, the heights (h3, h4) of the upper leg portion 128 and the lower leg portion 129 together define the inner height ‘h2’ of the inner seal leg 127. In one implementation, the height h4 of the lower leg portion 129 is defined such that there is sufficient room in the initial gap 131 to receive the folded lower leg portion 129 without touching (i.e., contacting) the outer seal leg 126. The flexing allows some portion of the lower leg portion 129 to be received into the groove 117 while ensuring the inner seal leg 127 of the barrier seal ring 125 fully blocks the gap between the TES ring 150 and the base ring 116. The length and angle of the inner corner chamfer C3 allows the lower leg portion 129 to fold easily into the initial gap 131 without interfering with the lower outer corner of the groove 117 while extending out to block the gap between the TES ring 150 and the base ring 116. Without the inner corner chamfer C3, the extent to which the outer seal leg 127 can be bent may be limited by one or more of the thickness of the lower leg portion 129 of the outer seal leg 127, the heights h1, h2 of the outer, outer seal legs and the height of the groove 117. In other words, the bottom surface of the outer seal leg 127 may hit the lower outer corner of the groove 117 and prevent the barrier seal ring from fully sit in the groove 117 during installation. Further, in one implementation, the heights (h3, h4) of the upper and lower leg portions (128, 129) and the extent of flexing of the lower leg portion 129 are defined to ensure that the lower leg portion 129, when folded, does not extend beyond the outer height h1 of the outer seal leg 126. In one implementation, the heights (h3, h4) of the upper and lower leg portions (128, 129) depend on the angle at which the upper leg portion 128 is disposed relative to the inside surface of the outer seal leg 126. In one implementation, the height h3 of the upper leg portion 128 is greater than the height h4 of the lower leg portion 129. In alternate implementations, the height h3 of the upper leg portion 128 is equal to or less than the height h4 of the lower leg portion 129. In one implementation, the height h3 of the upper leg portion 128 is between about 2.5 mm and about 2.7 mm. In alternate implementation, the height h3 of the upper leg portion 128 is defined to be about 2.62 mm. In one implementation, the height h4 of the lower leg portion 129 is defined to be between about 1.85 mm and about 2.05 mm. In alternate implementation, the height h4 of the lower leg portion 129 is defined to be about 1.95 mm. In one implementation, the angle at which the upper leg portion 128 extends from the inside surface of the outer seal leg 126 is defined by ‘α°’, wherein α° is an acute angle. In one implementation illustrated in FIG. 4, the α° is about 24°. In another implementation illustrated in FIG. 5, the α° is about 20°.

The interface represents the interface between the upper leg portion 128 and the lower leg portion 129. In one implementation, the interface is disposed at height h3 (i.e., height of the upper leg portion 128) from the top surface of the barrier seal ring 125. The interface allows the inner seal leg 127 to flex inward, when a force F is applied at the outer surface of the lower leg portion 129.

FIG. 5 illustrates the different positional profiles of the barrier seal ring, in one implementation. The inner seal leg 127 is represented by both a solid line and a broken line. The inner seal leg 127 represented by the solid line corresponds to the barrier seal ring 125 when in relaxed position and the broken line corresponds to the flexed position. The barrier seal ring 125 is moved to the flexed position by applying a force ‘F’ at the outside surface of the lower leg portion 129, when the TES ring 150 is being installed adjacent to inner diameter of the barrier seal ring 125 received inside the groove 117 defined in the base ring 116. In the implementation shown in FIG. 5, the upper leg portion 128 of the barrier seal ring 125 is oriented at an angle α° relative to the inside surface of the outer seal leg 126, wherein α° is defined to be an acute angle. When the force F is applied, the inner seal leg 127 is pushed inward toward the outer seal leg 126. As a result, the upper leg portion 128 and the lower leg portion 129 are pushed inwards. In one implementation, the amount to which upper leg portion 128 is pushed inward is less than the amount to which the lower leg portion 129 is pushed inward. The extent to which the upper leg portion 128 and the lower leg portion 129 of the inner seal leg 127 flexes is limited by the interface. In one implementation, due to the angled contour of the inner seal leg 127, the upper leg portion 128 of the inner seal leg 127 is pushed (i.e., flexed) inward by a first folding angle ‘a° ’ while the lower leg portion 129 of the inner seal leg 127 is flexed/pushed inward by a second folding angle ‘A° ’. In one implementation, the first folding angle a° of the upper leg portion 128 is less than the second folding angle A° of the lower leg portion 129. In an alternate implementation, the first folding angle a° of the upper leg portion 128 is equal to the second folding angle A° of the lower leg portion 129. In one implementation, the first folding angle a° of the upper leg portion 128 is less than the angle α° at which the upper leg portion 128 is disposed relative to the inside surface of the outer seal leg 126. In one implementation, the second folding angle A° of the lower leg portion 129 is greater than the angle α° at which the upper leg portion 128 is disposed relative to the inside surface of the outer seal leg 126. In an alternate implementation, the second folding angle A° of the lower leg portion 129 is less than or equal to the angle α° at which the upper leg portion 128 is disposed relative to the inside surface of the outer seal leg 126. In some implementations, the first and the second folding angles (a°, A°) to which the upper and the lower leg portions (128, 129) can be flexed/pushed are defined based on height h3 of the upper leg portion 128, height h4 of the lower leg portion 129, the initial angle α° that the upper leg portion 128 extends from the inside surface of the outer seal leg 126, amount of initial gap 131 defined between the inner seal leg 127 and the outer seal leg 126 when the barrier seal ring 125 is in the relaxed position, the amount of folded gap 132 that needs to be left between the inner seal leg 127 and the outer seal leg 126 when the barrier seal ring 125 is in the flexed position, and the amount of force F applied to the outside surface of the lower leg portion 129. The folded gap 132 is defined to prevent any interference between the outer seal leg 126 and the inner seal leg 127. Additionally, the first and second folding angles and the dimensions of the outer seal leg 126 and the inner seal leg 127 (i.e., upper leg portion 128, lower leg portion 129) are defined to ensure there are no interferences between any surface of the barrier seal ring 125 and the surfaces of the groove 117 and base ring 116. In one implementation, the interference, as used here, refers to an amount or extent to which the outer seal leg is prevented from being pushed into place inside the groove 117 due to the outer seal leg being prevented from bending by the lower outer corner of the groove 117, for example. Further, the first and the second folding angles, the height h3 of the upper leg portion 128 and the height h4 of the lower leg portion 129 are all defined to ensure that the lower leg portion 129 does not extend beyond the outer height h1 of the outer seal leg 126 when in the flexed position.

It should be noted that the design, the dimensions, the material used for defining the barrier seal ring 125 are all provided as examples and should not be considered exhaustive or limiting. Further, it is to be noted that the usage of the term “about” when defining the various dimensions (lengths and angles) of the barrier seal ring 125 may include a variation of +/−10-15% of the cited dimensions. In one implementation, the barrier seal ring 125 is made of a material that is less susceptible to erosion from fluorine and/or other reactive components of the plasma radicals so that the barrier seal ring 125 can be re-used in multiple operations, and is flexible to be pushed into place within the groove of the base ring 116. In some implementations, the barrier seal ring 125 is made of polytetrafluoroethylene (PTFE) or perfluoroelastomer (FFKM) material. In alternate implementations, the barrier seal ring 125 may be made of same or similar material as an O-ring that is used in the plasma chamber to prevent gas and fluid leaks. The barrier seal ring 125 is not restricted to the aforementioned materials but can be made of any other material with same or comparable thermal and chemical properties.

In one implementation, the barrier seal ring 125 may undergo annealing to maintain the original size when installed in the groove. The environment within the plasma chamber where the barrier seal ring 125 is being used can vary based on the operation being performed. As a result, the barrier seal ring 125 may shrink causing the barrier seal ring 125 to fail in blocking the plasma radicals from flowing toward and attacking the underlying parts, such as the insulating (plastic) components. To prevent the size and shape of the barrier seal ring 125 from getting affected when in use within the plasma chamber, the barrier seal ring undergoes an annealing process before it is installed in the groove 117 of the base ring 116. By undergoing annealing, the barrier seal ring 125 geometry is maintained during use, thereby ensuring that the function of the barrier seal ring 125 is not adversely affected by the conditions in the plasma chamber. The annealing process enables the barrier seal ring to retain its structure and size. The temperature and the time used for annealing depends on the material used and the aforementioned range of temperature and time are provided as examples and should not be considered restrictive.

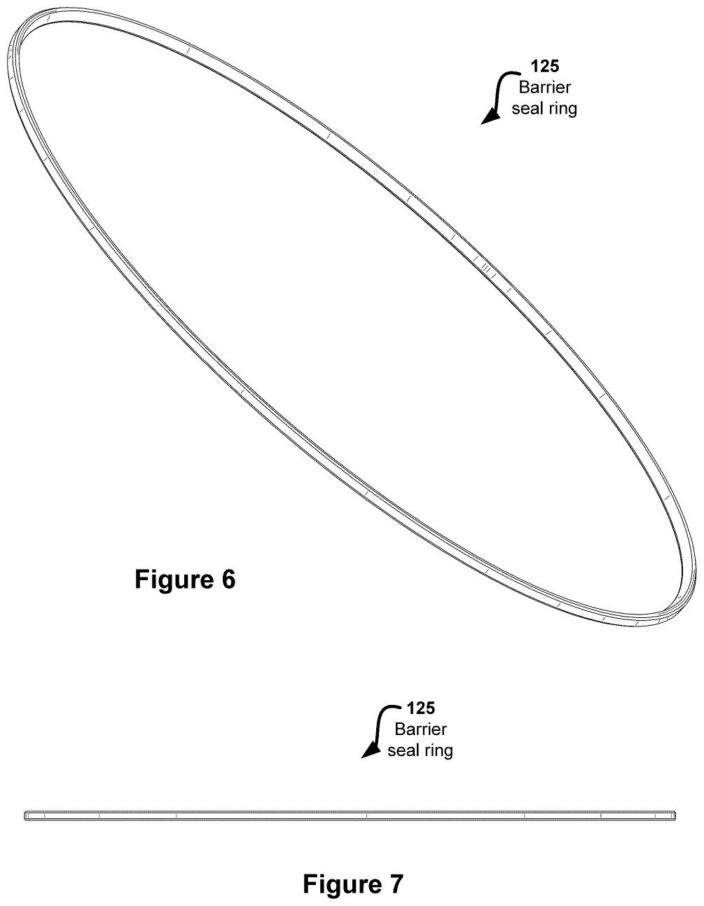

FIG. 6 illustrates a side view of the top perspective view of a plasma radical edge ring barrier seal 125 usable in a plasma chamber. The barrier seal 125 is in the shape of a ring and hence also referred to throughout this application as a “barrier seal ring” 125. The barrier seal ring 125 is configured to be integrated into a groove 117 defined on an inside surface of a base ring 116 disposed below an edge ring 112 surrounding an electrostatic chuck that is part of a lower electrode of the plasma chamber of the process module 100. The barrier seal ring 125 is used to seal a gap between the base ring 116 and a tunable edge sheath (TES) ring 150 that is part of a TES assembly disposed below the edge ring 112, wherein the TES assembly is used to provide power to control plasma sheath profile over the edge ring 112. Although the various implementations have been described with reference to the barrier seal ring 125 sealing a gap between the base ring 116 and the TES ring 150, the barrier seal ring 125 can also be used to seal the gaps between the edge ring 112 and the cover ring 114, between the edge ring 112 and base ring 116, between the cover ring 114 and the base ring 116, etc.

FIG. 7 illustrates a side view of the barrier seal ring 125 that is configured to seal gaps between the base ring 116 and other components disposed under the edge ring 112.

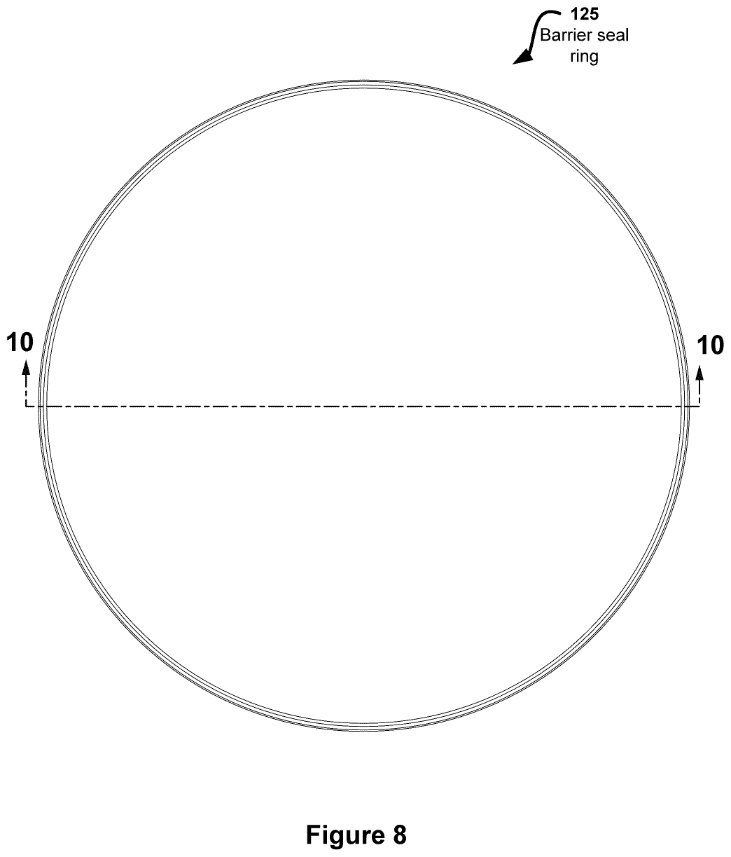

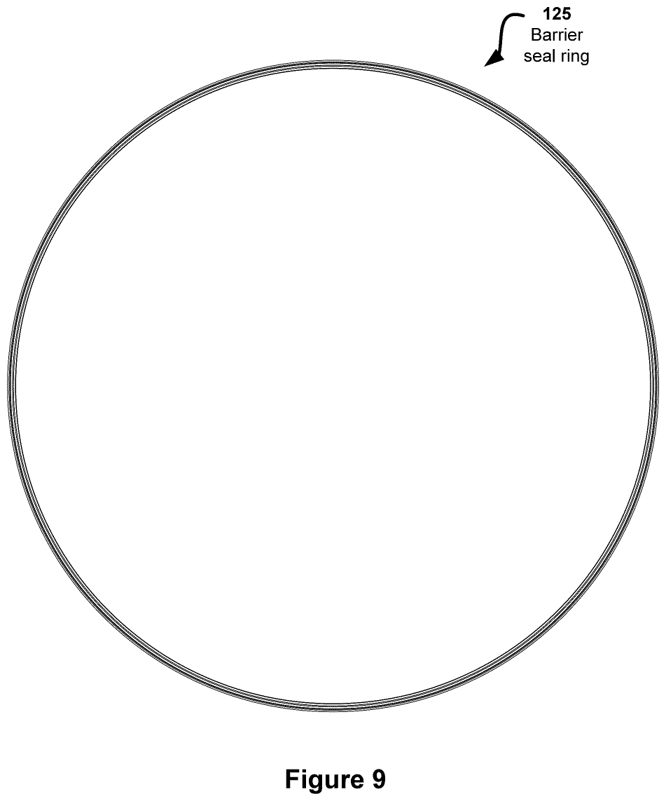

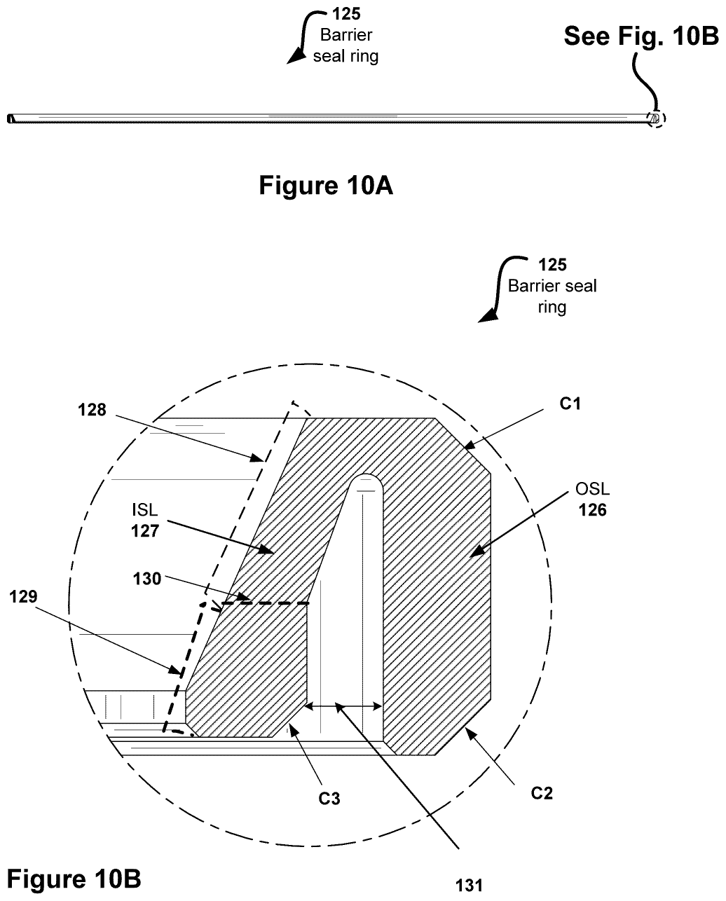

FIG. 8 illustrates a top view of the barrier seal ring 125 and FIG. 9 illustrates a bottom view of the barrier seal ring 125 used in the plasma chamber. A more detailed view of the barrier seal ring 125 is shown and discussed with reference to FIGS. 10A and 10B.

FIG. 10A illustrates a side view of a barrier seal ring 125 which shows a location from where a magnified cross-sectional view of the barrier seal ring is being provided in FIG. 10B. Referring simultaneously to FIGS. 10A and 10B, the barrier seal ring 125 includes a pair of legs, wherein a outer seal leg 126 is defined at an outer diameter OD and includes a sidewall with a chamfer (C1, C2) defined at the top and bottom surface of the sidewall, and an inner seal leg 127 is defined to extend to an inner diameter ID and includes an upper leg portion 128 and lower leg portion 129. The upper leg portion 128 extends at an angle from a top portion of the outer seal leg 126 so as to define an initial gap 131 between the outer seal leg 126 and the inner seal leg 127. An interface 130 is defined between the upper leg portion 128 and the lower leg portion 129 and is configured to allow the inner seal leg 127 to flex inward at the interface 130 toward the outer seal leg 126. The flexing of the inner seal leg 127 is limited to allow a folded gap 132 to be defined between the outer seal leg 126 and the inner seal leg 127. The folded gap 132 is to ensure there is no contact between the outer seal leg 126 and the lower leg portion 129 of the inner seal leg 127. The flexing allows the barrier seal ring 125 to fit snugly inside the groove 117 and the height h1 of the outer seal leg 126 is maximized to minimize clearance in the groove 117 of the base ring 116. Further, the outer height h1 of the outer seal leg 126 is defined to ensure the barrier seal ring 125 does not overfill the height of the groove as the barrier seal ring 125 is exposed to the temperature in the plasma chamber. The outer diameter OD of the barrier seal ring 125 is defined to ensure seal compression occurs during installation so that the barrier seal ring 125 can be reused and the installed easily. Chamfers (C1, C2) provided in the outer corners of the outer seal leg 126 ensure the barrier seal ring 125 fully mates with the inside surface of the groove 117 (i.e., abuts the length of the inside sidewall of the groove 117 except at the top and bottom outer corners where the chamfers C1 and C2 are defined) during installation. A chamfer C3 provided in the inside corner of the lower leg portion 129 of the inner seal leg 127 allows the inner seal leg 127 to flex easily without contacting the outer corner of the groove 117 (i.e., the lower outer corner that is facing the TES ring 150) of the base ring 116. Without chamfer C3, in some instances, the flexing of the inner seal leg 127 may damage the barrier seal ring 125 at the inner corner of the inner seal leg 127 or may be hard to push the inner seal leg 127 inward. The lower width w2 of the barrier seal ring 125 is defined to ensure contact between the barrier seal ring 125 and the TES ring 150 so as to block the gap between the TES ring 150 and the base ring 116. The inner height h2 is defined to ensure that the inner seal leg 127 has room to fold into the groove 117.

1. A barrier seal ring for use in a plasma chamber, the barrier seal ring comprising:
an outer seal leg extending vertically down at an outer diameter, the outer seal leg having an upper chamfer and a lower chamfer on an outside surface;
an inner seal leg connected to a top portion of the outer seal leg, the inner seal leg oriented at an angle relative to the outer seal leg and the inner seal leg comprises an upper leg portion and a lower leg portion, wherein the lower leg portion of the inner seal leg forms an initial gap of a first distance with the outer seal leg;
the lower leg portion is configured to flex towards the outer seal leg to create a second gap that is less than the first distance of the initial gap but greater than zero;
wherein the barrier seal ring is configured to sit in a groove of a first ring and provide a seal when the inner seal leg is pressed against a second ring, said first and second rings being part of the plasma chamber.

2. The barrier seal ring of claim 1, wherein the inner seal leg is oriented at an acute angle relative to the outer seal leg,
wherein the first ring is a base ring disposed below an edge ring surrounding a substrate support surface disposed in a lower portion of the plasma chamber, and the second ring is a coupling ring that is part of a tunable edge sheath (TES) assembly disposed adjacent to and surrounded by said base ring.

3. The barrier seal ring of claim 1, wherein an interface in the inner seal leg connects the upper leg portion to the lower leg portion, and wherein said inner seal leg flexes inward along said interface and said flexing varies in degree for each of said upper leg portion and said lower leg portion.

4. The barrier seal ring of claim 3, wherein said upper leg portion flexes at a first folding angle and said lower leg portion flexes at a second folding angle, and wherein the first folding angle is less than the second folding angle.

5. The barrier seal ring of claim 3, wherein an inside surface of the lower leg portion extends vertically down and is parallel to an inside surface of the outer seal leg, and
wherein an outer surface of said lower leg portion includes a top portion and a bottom portion, said top portion extends a first height and follows a contour of an outside surface of the upper leg portion, and the bottom portion extends a second height vertically down to an inner diameter of the barrier seal ring.

6. The barrier seal ring of claim 3, wherein said outer seal leg at the outer diameter extends a first height and the inner seal leg extends to an inner diameter for a second height, wherein the first height is greater than the second height,
wherein said upper leg portion extends a third height and said lower leg portion extends a fourth height, said third height and said fourth height define the second height of the inner seal leg.

7. The barrier seal ring of claim 1, wherein said inner seal leg has an inner chamfer defined in an inside surface.

8. The barrier seal ring of claim 1, wherein profile of said upper chamfer and said lower chamfer match a profile at corresponding inner radii of a top corner and a bottom corner of an inside sidewall of said groove of said first ring.

9. The barrier seal ring of claim 1, wherein a top width of said barrier seal ring is less than a bottom width of said barrier seal ring.

10. The barrier seal ring of claim 1, wherein the groove is defined on an inside sidewall of the first ring disposed in a lower portion of the plasma chamber, the groove extends inward from a first inner diameter to a second inner diameter,
wherein the second inner diameter of the groove of said first ring is equal to the outer diameter of said barrier seal ring and said upper and lower chamfers of the outer seal leg of the barrier seal ring are defined to allow full mating of the outer seal leg at the outer diameter with the inside sidewall of the groove defined in the first ring.

11. The barrier seal ring of claim 1, wherein a height of the groove defined in the first ring is equal to a first height of the outer seal leg at the outer diameter.

12. The barrier seal ring of claim 10, wherein said first ring and said second ring are part of a tunable edge sheath (TES) assembly defined in a lower portion of the plasma chamber, wherein the TES assembly includes,
said first ring disposed below a first portion of an edge ring surrounding an electrostatic chuck (ESC) disposed in a center of a lower portion of said plasma chamber,
said second ring is disposed below a second portion of said edge ring, the second ring includes a coupler embedded within and proximate to a top surface of said second ring,
a ceramic support element disposed below said second ring and surround the ESC, the ceramic support element including a sleeve received in a vertical shaft extending a height of the ceramic support element, the sleeve being an insulating component configured to encapsulate a conductive rod, and
a radio frequency (RF) power source with a matching network,
wherein a first end of the conductive rod is coupled to the RF power source through the matching network and a second end of the conductive rod is coupled to the coupler embedded in the second ring, the conductive rod extending through the insulating component to a base of the coupler in the second ring, the conductive rod configured to transmit power from the RF power source to said edge ring so as to influence sheath profile of plasma generated in a plasma processing region of the plasma chamber and extended over the edge ring.

13. The barrier seal ring of claim 12, wherein a second RF power source is coupled to the ESC through a second matching network to provide power to the ESC to generate the plasma in the plasma processing region.

14. The barrier seal ring of claim 1, wherein the barrier seal ring is annealed to prevent shrinkage of the barrier seal ring, when in use.

15. The barrier seal ring of claim 1, wherein the barrier seal ring is made of polytetrafluoroethylene or perfluoroelastomer material.
